(19) United States
(12) Patent Application Publication
(10) Pub. No.: US 2009/0185096 A1
(43) Pub. Date: Jul. 23, 2009

(54) PRINTED CIRCUIT BOARD, METHOD OF MOUNTING SURFACE MOUNTED DEVICES ON THE PRINTED CIRCUIT BOARD AND LIQUID CRYSTAL DISPLAY INCLUDING THE PRINTED CIRCUIT BOARD

(75) Inventor: Yong-Eun PARK, Suwon-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/196,306

(22) Filed: Aug. 22, 2008

(30) Foreign Application Priority Data
Jan. 18, 2008 (KR) 10-2008-0005835

(51) Int. Cl. H05K 1/16; B23K 1/00; G02F 1/1333

(52) U.S. Cl. 349/56; 228/179.1; 174/260

(57) ABSTRACT

A printed circuit board includes; first and second pads spaced apart from each other; and a dielectric region which surrounds the first and second pads, wherein each of the first and second pads includes a main region and an expansion region which extends from the main region, and wherein the main regions of the first and second pads are configured to have a first surface mount device mounted thereon, wherein the expansion regions and portions of the main regions which directly adjoin the expansion regions of the first and second pads are configured to have a second surface mount device mounted thereon, and wherein the first and second surface mount devices have different sizes.

This application claims priority to Korean Patent Application No. 10-2008-0005835, filed on Jan. 18, 2008, and all the benefits accruing therefrom under 35 U.S.C. §119, the contents of which in its entirety are herein incorporated by reference.

### BACKGROUND OF THE INVENTION

1. Field of the Invention

The present invention relates to a printed circuit board (“PCB”), a method of mounting the PCB, and a liquid crystal display (“LCD”) including the PCB, and, more particularly, to a PCB, a method of mounting surface-mounted devices (“SMDs”) on the PCB, and an LCD including the PCB that contributes to the improvement of sourcing flexibility for SMDs and the reduction of manufacturing costs.

2. Description of the Related Art

A liquid crystal display (“LCD”) includes a display unit which displays an image and a backlight unit which provides backlight to the display unit. The display unit includes a liquid crystal panel and a first printed circuit board (“PCB”) for driving the liquid crystal panel. The liquid crystal panel includes a first substrate on which pixel electrodes are formed, a second substrate on which common electrodes are formed and a liquid crystal layer which is interposed between the first substrate and the second substrate. The backlight unit includes a light source module and a second PCB for driving the light source module.

An LCD having the above-mentioned structure generates an electric field between pixel electrodes and common electrodes, and adjusts the intensity of the electric field so that the alignment of liquid crystal molecules in a liquid crystal layer can be altered, and thereby controls the amount of light transmitted through the liquid crystal layer. In this manner, an LCD can display a desired image.

Surface mount devices (“SMDs”) are mounted on the first and second PCBs. The first and second PCBs include pads for mounting SMDs. The pads for mounting SMDs come in standard sizes and only SMDs having sizes corresponding to those standards can be mounted on such pads. That is, the size of SMDs that can be mounted on conventional PCBs is restricted. As a result, sourcing flexibility for SMDs deteriorates, and the cost of manufacturing PCBs with the SMDs increases. In addition, conventional PCBs may not be able to readily respond to the necessity of design modifications, e.g., for market demands or improved price competitiveness.

### BRIEF SUMMARY OF THE INVENTION

An exemplary embodiment of the present invention provides a printed circuit board (“PCB”) which contributes to improved sourcing flexibility for surface-mount devices (“SMDs”) and the reduction of manufacturing costs.

Exemplary embodiments of the present invention also provide a method of mounting SMDs on a PCB which contributes to the improved sourcing flexibility for SMDs and the reduction of manufacturing costs.

Exemplary embodiments of the present invention also provide a liquid crystal display (“LCD”) including a PCB which contributes to improved sourcing flexibility for SMDs and the reduction of manufacturing costs.

However, the objectives of the present invention are not restricted to those set forth herein. The above and other objectives of the present invention will become apparent to one of daily skill in the art to which the present invention pertains by referencing a detailed description of the present invention given below.

According to an exemplary embodiment of the present invention, there is provided a PCB including; first and second pads spaced apart from each other, and a dielectric region which surrounds the first and second pads, wherein each of the first and second pads includes a main region and an expansion region which extends from the main region, and wherein the main regions of the first and second pads are configured to have a first SMD mounted thereon, wherein the expansion regions and portions of the main regions which directly adjoin the expansion regions of the first and second pads are configured to have a second SMD mounted thereon, and wherein the first and second surface mount devices have different sizes.

According to another exemplary embodiment of the present invention, there is provided a method of mounting a SMD on a PCB, the mounting method including; providing a PCB which includes; first and second pads spaced apart from each other, and a dielectric region which surrounds the first and second pads, wherein each of the first and second pads including a main region and an expansion region which extends from the main region; and mounting one of a first SMD on the main regions of the first and second pads and mounting a second SMD on the extend regions and portions of the main regions which directly adjoin the expansion regions of the first and second pads.

According to another exemplary embodiment of the present invention, there is provided an LCD including; a display unit which includes a liquid crystal panel and a first PCB configured to drive the liquid crystal panel, and a backlight unit which includes a light source module and a second PCB configured to drive the light source module and provide backlight to the display unit, wherein at least one of the first and second PCB includes; first and second pads which are spaced apart from each other, and a dielectric region which surrounds the first and second pads, wherein each of the first and second pads includes a main region and an expansion region which extends from the main region, and wherein the main regions of the first and second pads are configured to have a first SMD mounted thereon, wherein the expansion regions and portions of the main regions which directly adjoin the expansion regions of the first and second pads are configured to have a second SMD mounted thereon, and wherein the first and second SMDs have different sizes.

### BRIEF DESCRIPTION OF THE DRAWINGS

The above and other features and advantages of the present invention will become apparent by describing in detail exemplary embodiments thereof with reference to the attached drawings in which:

FIG. 1 illustrates an exploded perspective view of an exemplary embodiment of a liquid crystal display (“LCD”) according to the present invention;

FIG. 2 illustrates a front perspective view of an exemplary embodiment of a display unit illustrated in FIG. 1;

FIG. 3 illustrates a top plan view of an exemplary embodiment of a PCB according to the present invention;

FIG. 4 illustrates a partial cross-sectional view taken along line V-V′ of FIG. 3;

FIG. 5 illustrates a partial cross-sectional view of a structure resulting from mounting an exemplary embodiment of a first surface mount device (“SMD”) on the exemplary embodiment of a PCB illustrated in FIG. 4;

FIG. 6 illustrates a partial cross-sectional view of a structure resulting from mounting an exemplary embodiment of a second SMD on the exemplary embodiment of a PCB illustrated in FIG. 4;

FIG. 7 illustrates a top plan view of another exemplary embodiment of a PCB according to the present invention;

FIG. 8 illustrates a top plan view of another exemplary embodiment of a PCB according to the present invention;

FIG. 9 illustrates a top plan view of another exemplary embodiment of a PCB according to the present invention; and

FIG. 10 illustrates a schematic diagram of various exemplary embodiments of the shape of sub-expansion regions illustrated in FIG. 9.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

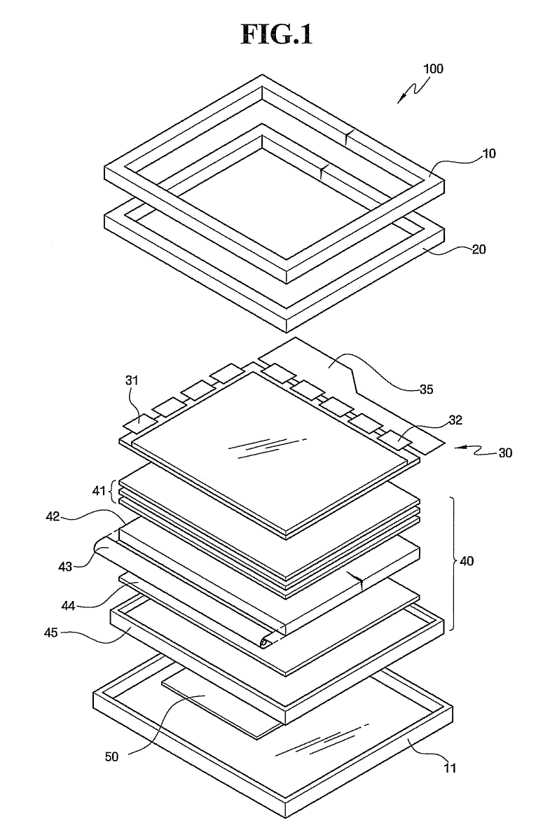

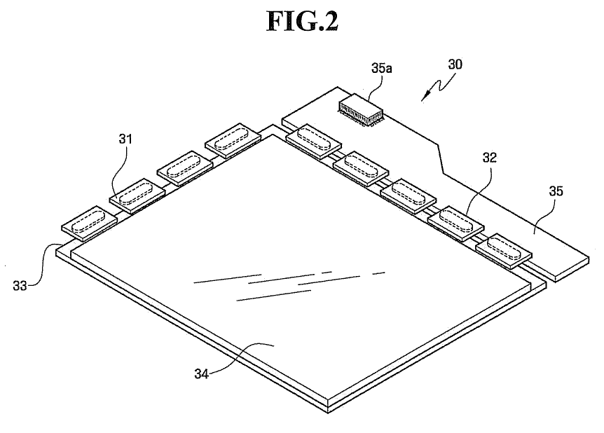

An exemplary embodiment of a liquid crystal display (“LCD”) including an exemplary embodiment of a printed circuit board (“PCB”) according to the present invention will hereinafter be described in detail with reference to FIGS. 1 and 2.

FIG. 1 illustrates an exploded perspective view of an exemplary embodiment of an LCD 100 according to the present invention, FIG. 2 illustrates a front perspective view of an exemplary embodiment of a display unit 30 illustrated in FIG. 1.

Referring to FIG. 1, the LCD 100 includes a display unit 30, a backlight unit 40, a chassis 20, a top cover 10 and a bottom cover 11. In addition, referring to FIG. 2, the display unit 30 includes a first substrate 33, a second substrate 34 which faces the first substrate 33, a liquid crystal layer (not shown) which is interposed between the first substrate 33 and the second substrate 34, a plurality of gate tape carrier packages (“TCPs”) 31, a plurality of data TCPs 32, and a first PCB 35.

The first substrate 33 may be a thin-film transistor (“TFT”) substrate on which a plurality of TFTs is formed as a matrix. A plurality of data lines (not shown) may be respectively connected to the source terminals of the TFTs, and a plurality of gate lines (not shown) may be respectively connected to the gate terminals of the TFTs, and a plurality of pixel electrodes (not shown) may be respectively connected to the drain terminals of the TFTs.

The second substrate 34 may be a color filter substrate on which a plurality of red (R) green (G) and blue (B) pixels (not shown) is formed as thin films for rendering colors. A plurality of common electrodes (not shown) may be formed of a transparent conductive material on the second substrate 34. Alternative exemplary embodiments include configurations wherein a single common electrode is formed on substantially the entire second substrate 34.

The alignment of liquid crystal molecules in the liquid crystal layer, which is interposed between the first substrate 33 and the second substrate 34, varies according to an electric field generated between the first substrate 33 and the second substrate 34 by the pixel electrodes and the common electrodes.

The gate TCPs 31 are respectively connected to the gate lines on the first substrate 33, and the data TCPs 32 are respectively connected to the data lines on the first substrate 33. In the present exemplary embodiment, a driving element 35a for processing gate-driving signals and data-driving signals is mounted on the first PCB 35. The driving element 35a, the gate TCPs 31 and the data TCPs 32 generate a gate signal and an image data voltage. The gate signal may be provided to each of the gate lines, and the image data voltage may be provided to each of the data lines.

An exemplary embodiment of an integrated circuit (“IC”) for generating the gate signal and the image data voltage is illustrated in FIGS. 1 and 2 as TCPs, but the present invention is not limited thereto. In an alternative exemplary embodiment, the IC for generating the gate signal and the image data voltage may be realized as a chip-on-film (“COF”). In additional alternative exemplary embodiments, the IC for generating the gate signal and the image data voltage may be directly mounted on the first substrate 33.

Referring to FIG. 1, the backlight unit 40 includes a light source module 43, a light guide plate 42, one or more optical sheets 41 which are disposed on the light guide plate 42, a reflective sheet 44 which is disposed below the light guide plate 42, a mold frame 45 and the second PCB 50.

The light source module 43 may include a light source which generates light and a light source cover which protects the light source. In one exemplary embodiment, the light source may be a cold cathode fluorescent lamp (“CCFL”) which is formed as a long thin cylinder. Alternative exemplary embodiments include configurations wherein, the light source may be an external electrode fluorescent lamp (“EEFL”) having a pair of electrodes respectively disposed on both sides of the EEFL. The light source cover protects the light source by surrounding three sides of the light source. The light source cover reflects light emitted from the light source toward the light guide plate 42, and can thus improve the efficiency of the use of light.

The light guide plate 42 guides light emitted from the light source module 43 toward the display unit 30. In one exemplary embodiment, the light guide plate 42 may be formed of polymethylmethacrylate (“PMMA”) or other substances with similar characteristics. In one exemplary embodiment, the light guide plate 42 may have a uniform thickness. Alternative exemplary embodiments include configurations wherein, the light guide plate 42 may be formed as a wedge, and, thus, the thickness of the light guide plate 42 may decrease with distance from the light source module 43.

The optical sheets 41 may be disposed on the light guide plate 42 and may improve the luminance of light emitted from the light guide plate 42. The optical sheets 41 diffuse and collect light emitted from the light guide plate 42. In one exemplary embodiment, the optical sheets 41 may include at least one of a diffusive sheet, a prism sheet and a protective sheet.

The optical sheets 41, specifically the diffusive sheet, can address the problems associated with the quality of the external appearance of the light guide plate 42, such as bright lines, dark lines, or dark corner areas by diffusing light from the light guide plate 42 before introducing it into the display unit 30. The prism sheet includes a plurality of prism patterns (not shown) formed thereon, and may collect light emitted from the light guide plate 42 and direct it in a planarized manner towards the display unit 30, thereby increasing the total luminance of the LCD 100. The protective sheet may be disposed on the prism sheet and may thus protect the prism sheet. In addition, the protective sheet may prevent the prism sheet from being firmly attached to the display unit 30 and may thus improve the external appearance of the liquid crystal panel by preventing the generation of artifacts arising from contact between the prism sheet and the display unit 30.

The reflective sheet 44 reflects light leaked from the bottom of the light guide plate 42 back toward the light guide plate 42. The reflective sheet 44 may be formed of a material with high light reflectance. In one exemplary embodiment, the reflective sheet 44 may be formed of a white polyethyleneterephthalate (“PET”) material or a white polycarbonate (“PC”) material.

The mold frame 45 holds and fixes the backlight unit 40 therein.

An inverter(not shown) for supplying power to the light source of the light source module 43 is formed on the second PCB 50 for driving the light source module 43. In one exemplary embodiment, the light source and the inverter are electrically connected by wires.

When power is applied to the gate terminals of the TFTs on the first substrate 33, and thus the TFTs are turned on, an electric field may be generated between the pixel electrodes and the common electrodes, the magnitude of the electric field depending upon the data signals applied to the source terminals of the TFTs and the voltage applied to the common electrodes. Due to the electric field, the alignment of liquid crystal molecules in the liquid crystal layer between the first substrate 33 and the second substrate 34 varies, and thus, the transmittance of the liquid crystal layer varies. In this manner, the LCD 100 can display an image with a desired grayscale level.

Referring to FIG. 1, in one exemplary embodiment, the chassis 20 may be formed of a metal. The chassis 20 may be electrically connected to the first PCB 35 and/or the second PCB 50 and may thus serve as an electric ground for providing a ground voltage to the first PCB 35 and/or the second PCB 50.

In the current exemplary embodiment, the bottom cover 11 is formed as an open box and forms the bottom of the LCD 100.Additionally, in the present exemplary embodiment, the top cover 10 is formed in an open rectangular shape, similar to a window frame, and forms the top of the LCD 100. The top cover 10 holds the display unit 30 therein. The top cover 10 may be coupled to the bottom cover 11 and may thus prevent the display unit 30 from being detached.

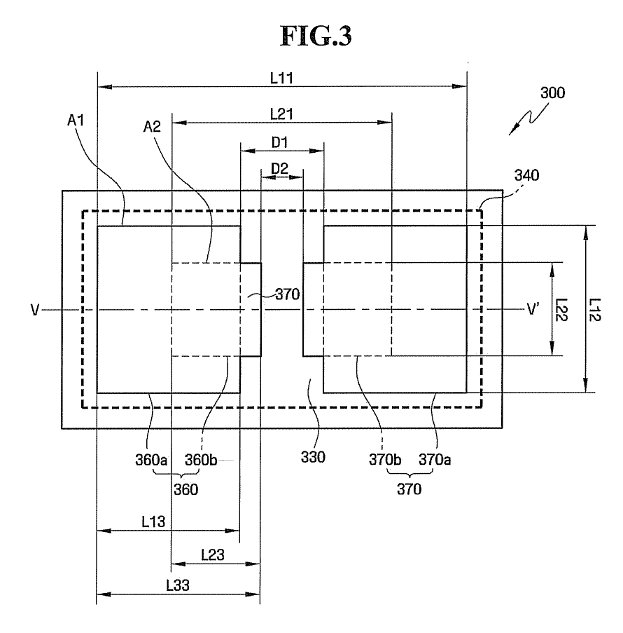

An exemplary embodiment of a PCB 300 according to the present invention will hereinafter be described in detail with reference to FIGS. 3 through 6. The PCB 300 may be the first PCB 35 or the second PCB 50 illustrated in FIGS. 1 and 2. An SMD may be mounted on the PCB 300. Examples of the SMD include passive devices (such as resistors and capacitors), thin small outline packages (“TSOPs”), small outline J-lead packages (“SOJs”), ball grid arrays (“BGAs”) and active devices.

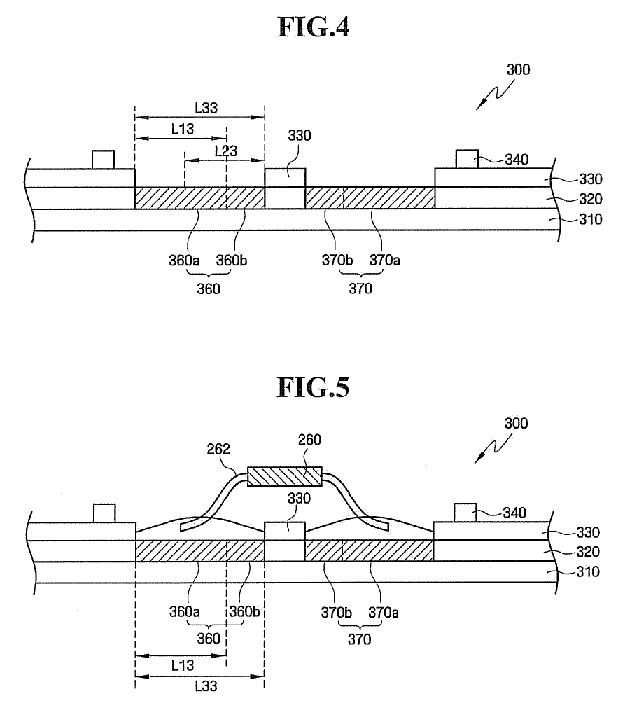

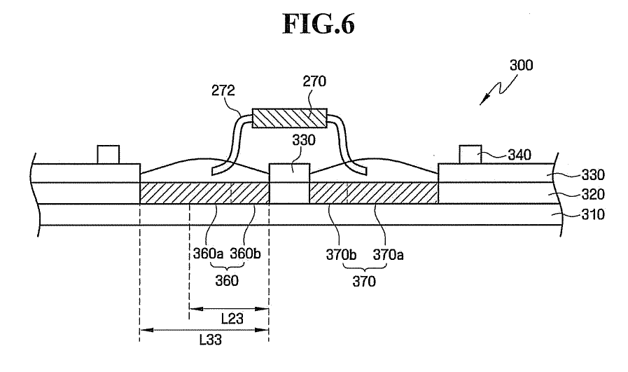

FIG. 3 illustrates a top plan view of the PCB 300, FIG. 4 illustrates a partial cross-sectional view taken along line V-V′ of FIG. 3, FIG. 5 illustrates a partial cross-sectional view of a structure resulting from mounting a first SMD 260 on the PCB 300 and FIG. 6 illustrates a partial cross-sectional view of a structure resulting from mounting an exemplary embodiment of a second SMD 270 on the exemplary embodiment of a PCB 300 illustrated in FIG. 4.

Referring to FIGS. 3 and 4, the PCB 300 includes an insulating substrate 310, exemplary embodiments of which may be formed of a dielectric material; an interconnection layer 320 which forms a circuit pattern on the insulating substrate 310; first and second pads 360 and 370, respectively, on which SMDs are mounted, and which each include a main region 360a and 370a, respectively, and an expansion region 360b and 370b, respectively; and a dielectric region 330 which is formed on the interconnection layer 320 and, in one exemplary embodiment, may be formed of solder resist.

The interconnection layer 320 includes conductive materials forming the first and second pads 360 and 370, respectively, which constitute circuit interconnection and a dielectric material disposed between first and second pads 360 and 370, and may thus form a circuit pattern. The exemplary embodiment of a PCB 300 illustrated in FIG. 4 includes a single layer structure for the interconnection layer 320, but the present invention is not restricted to such an embodiment. That is, the present invention can be applied to a multilayer PCB including a stacked structure of a dielectric layer and an interconnection layer, which form a circuit pattern.

The first and second pads 360 and 370 are spaced apart from each other. Referring to FIGS. 5 and 6, the first SMD 260 or the second SMD 270 may be mounted on the first and second pad 360 and 370.

Referring again to FIG. 3, each of the first and second pads 360 and 370 includes a main region 360a and 370a, respectively, and an expansion region 360b and 370b, respectively, which extends therefrom. The first SMD 260 may be mounted over first pad areas A1 of the first and second pads 360 and 370, and the second SMD 270 may be mounted over second pad areas A2 of the first and second pads 360 and 370. Each of the first pad areas A1 of the first and second pads 360 and 370 accounts for an entire main region 360a and 370a, respectively, and each of the second pad areas A2 of the first and second pads accounts for an entire expansion region 360b and 370b, respectively, and part of a main region 360a and 370a which directly adjoins the expansion region 360b and 360b.

The size of the first pad areas A1 of the first and second pads 360 and 370 may be determined according to the size of the first SMD 260, and the size of the second pad areas A2 of the first and second pads 360 and 370 may be determined according to the size of the second SMD 270.

Specifically, the first pad areas A1 of the first and second pads 360 and 370 may be defined by L12 and L13, and the second pad areas A2 of the first and second pads 360 and 370 may be defined by L22 and L23. The first and second SMDs 260 and 270 have different sizes, and thus, the sizes of the first and second pads 360 and 370 may vary according to the sizes of the first and second SMDs 260 and 260, respectively. For example, the first SMD 260 may have a standard package size of 1608 (metric), and the second SMD 270 may have a standard package size of 1005 (metric), as are commonly known in the surface mounting industry.

Each of the first pad areas A1 of the first and second pads 360 and 370 accounts for an entire main region 360a and 370a, respectively, and is defined by L12 and L13. The first pad area A1 of the first pad 360 is a predetermined distance D1 apart from the first pad area A1 of the second pad 370. The distance D1 may be predetermined according to the size of the first SMD 260.

Each of the second pad areas A2 of the first and second pads 360 and 370 accounts for an entire expansion region 360b and 370b and part of a main region 360a and 470a that directly adjoins the expansion region 360b and 370b, and is defined by L22 and L23. The second pad area A2 of the first pad 360 is spaced a predetermined distance D2 apart from the second pad area A2 of the second pad 370. The distance D2 may be predetermined according to the size of the second SMD 270.

Since L13 and L23 partially overlap each other, the sum of the lengths of the main region 360a and 370a and the expansion region 360b and 370b of each of the first and second pads 360 and 370 maybe L33, which is less than the sum of L13 and L23.

The expansion region 360b of the first pad 360 and the expansion region 370b of the second pad 370 extend from the main region 360a of the first pad 360 and the main region 370a of the second pad 370, respectively, so as to face each other. In addition, the expansion region 360b of the first pad 360 and the expansion region 370b of the second pad 370 may extend from a middle part of the main region 360a of the first pad 360 and a middle part of the main region 370a of the second pad 370, respectively, so as to face each other. Then, even SMDs having different sizes can be mounted on the same position of the PCB 300. Therefore, it is possible to automatically mount SMDs on the PCB 300, regardless of the size of SMDs, by using automated mounting equipment.

The dielectric region 330 surrounds the first and second pads 360 and 370. The dielectric region 330 may be formed by applying solder resist on the entire surface of the interconnection layer 320 except for portions electrically connected to the outside of the PCB 300; that is, except for portions where the first and second pads 360 and 370 are located.

In one exemplary embodiment, solder resist may be applied on the PCB 300 by using a screen printing method or a roller coating method. Solder resist may prevent the leak of solder from solder bodies (e.g., solder bumps) on the first and second pads 360 and 370 or the formation of solder bridges. In addition, solder resist may protect a circuit pattern exposed on the PCB 300.

Silk lines 340 may be printed on the PCB 300. In one exemplary embodiment, the silk lines 340 may form a rectangular outline and surround the first and second pads 360 and 370. The silk lines 340 may indicate the first and second pad areas A1 and A2 of each of the first and second pads 360 and 370 over which the first SMD 260 and the second SMD 270 may be mounted.

Referring to FIGS. 3 and 5, the first SMD 260 is mounted to substantially overlap the first pad areas A1 of the first and second pads 360 and 370. Each of the first pad areas A1 of the first and second pads is defined by L12 and L13 and accounts for an entire main region 360a and 370a. Referring to FIGS. 3 and 6, the second SMD 270 is mounted to substantially overlap only the second pad areas A2 of the first and second pads 360 and 370. Each of the second pad areas A2 of the first and second pads 360 and 370 is defined by L22 and L23 and accounts for an entire expansion region 360b and 370b and part of a main region 360a and 370b that directly adjoins the corresponding expansion region 360b and 370b.

An exemplary embodiment of the mounting of the first or second SMD 260 or 270 on the first or second pad 360 and 370 will hereinafter be described in detail.

Solder 380 is applied on the first and second pads 360 and 370, which are formed on the PCB 300. Specifically, in one exemplary embodiment, a metal mask (not shown) having openings that conform to the shapes of the first and second pads 360 and 370 is placed over the PCB 300, and cream solder is applied on the PCB 300 by using the metal mask and appropriately heating the PCB 300. Exemplary embodiments of the cream solder may include Au—Sn, Pb—Sn, Sb—Sn or other materials with similar characteristics.

Thereafter, leads 262 of the first SMD 260 or leads 272 of the second SMD 270 are bonded to the first and second pads 360 and 370. Specifically, once a thin layer of solder 380 is formed on the first and second pads 360 and 370, the leads 262 or the leads 272 are placed on the thin layer of solder 380. Thereafter, the PCB 300 is placed in an oven and heated to a temperature higher than the melting temperature of solder, thereby bonding the leads 262 or the leads 272 to the first and second pads 360 and 370.

According to the exemplary embodiment illustrated in FIG. 3, SMDs having different sizes may be mounted on the same position of the PCB 300. Thus, it is possible to improve sourcing flexibility for SMDs. Therefore, it is possible to secure the flexibility of supply chain management (“SCM”), and improve competitiveness for reducing manufacturing costs.

In addition, according to the exemplary embodiment illustrated in FIG. 3, it is possible to readily respond to the necessity of design modifications for market demands or improving price competitiveness. That is, since the PCB 300 does not impose restrictions on the size of SMDs that may be mounted thereon, the PCB 300 does not require design modifications, which are generally time and effort consuming.

For example, if the first SMD 260 is a resistor having a standard package size of 1608 (metric) and the second SMD 270 is a resistor having a standard package size of 1005 (metric), the benefits of a resistor having a standard package size 1608 (metric), such as a wide range of resistance values and high accuracy, and the benefits of a resistor having a standard package size of 1005 (metric) such as low manufacturing cost, may be selectively offered.

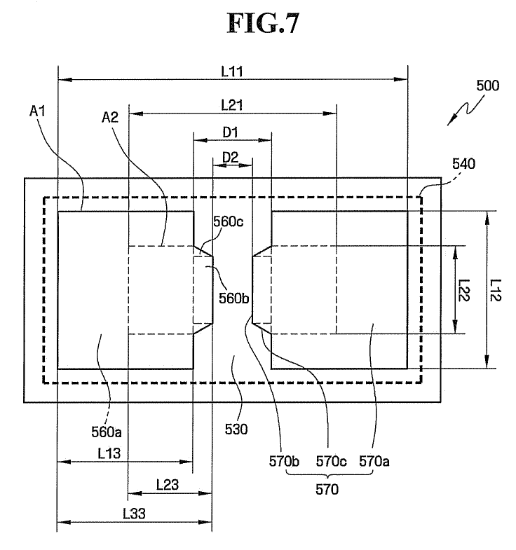

Another exemplary embodiment of a PCB 500 according to the present invention will hereinafter be described in detail with reference to FIG. 7. FIG. 7 illustrates a top plan view of the PCB 500. The exemplary embodiment of a PCB 500 illustrated in FIG. 7 is similar to the exemplary embodiment of a PCB 300 illustrated in FIG. 3, and therefore like reference numerals will indicate like elements, and detailed descriptions thereof will be skipped.

Referring to FIG. 7, the PCB 500 includes first and second pads 560 and 570 on which SMDs (not shown) can be mounted, and a dielectric region 530 on which no SMDs are mounted and which may be formed of solder resist. Silk lines 540 may be printed on the PCB 500.

Each of the first and second pads 560 and 570 includes a main region 560a and 570a, respectively, and an expansion region 560b and 560c, and 570b and 570c, respectively, which extend from the main region 560a and 570a. A first SMD (not shown) may be mounted over first pad areas A1 of the first and second pad 560 and 570, and a second SMD (not shown) may be mounted over second pad areas A2 of the first and second pad 560 and 570. Each of the first pad areas A1 of the first and second pads 560 and 570 accounts for an entire main region 560a and 570a, and is defined by L12 and L13. Each of the second pad areas A2 of the first and second pads 560 and 570 accounts for expansion regions (560b and 560c, and 570b and 570c) and part of a main region 560a and 570a that directly adjoins the expansion regions (560b and 560c, and 570b and 570c) and is defined by L22 and L23.

The expansion regions (560b and 560c, and 570b and 570c) of each of the first and second pads 560 and 570 include a main expansion region 560b and 570b, respectively, which has a uniform width and a pair of sub-expansion regions 560c and 570c, respectively, which are disposed on both sides of the main expansion region 560b and 570b and have a decreasing width.

A distance D1 between the main region 560a of the first pad 560 and the main region 570a of the second pad 570 may be predetermined according to the size of the first SMD. A distance D2 between the main expansion region 560b of the first pad 560 and the main expansion region 570b of the second pad 570 may be predetermined according to the size of the second SMD. The distance between the sub-expansion regions 560c of the first pad 560 and the sub-expansion regions 570c of the second pad 570 is greater than the distance D1 and less than the distance D2. In the present exemplary embodiment, the expansion regions (560b and 560c, and 570b and 570c) of each of the first and second pads 560 and 570 may form the shape of a trapezoid.

Since the expansion regions (560b and 560c, and 570b and 570c) of each of the first and second pads 560 and 570 include the main expansion region 560b and 570b and the sub-expansion regions 560c and 570c, the dielectric area between the first and second pads may be larger than in the embodiment of FIG. 3. Therefore, it is possible to reduce the probability of the occurrence of a short circuit due to first and second pads 560 and 570 being insufficiently spaced apart from each other.

The exemplary embodiment of a PCB 500 provides a larger dielectric area between first and second pads 560 and 570 but smaller pad areas A2 for mounting a second SMD than the exemplary embodiment of a PCB 300 illustrated in FIG. 3. However, in the exemplary embodiment illustrated in FIG. 7, it is possible to bond a second SMD to a first or second pad 560 and 570 by inserting solder not only into second pad areas A2 but also into first pad areas A1. Thus, it is possible to reduce the probability of cold soldering occurring due to lack of solder.

According to the exemplary embodiment illustrated in FIG. 7, it is possible to improve sourcing flexibility for SMDs and reduce manufacturing costs. In addition, it is possible to readily respond to the necessity of design modifications for market demands or improving price competitiveness.

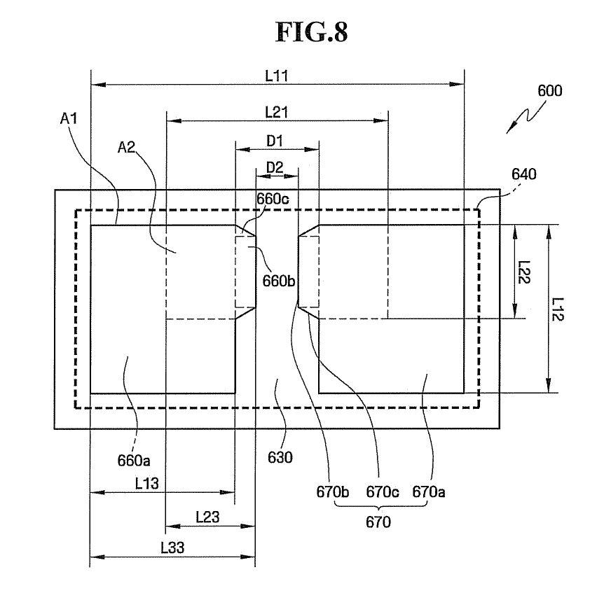

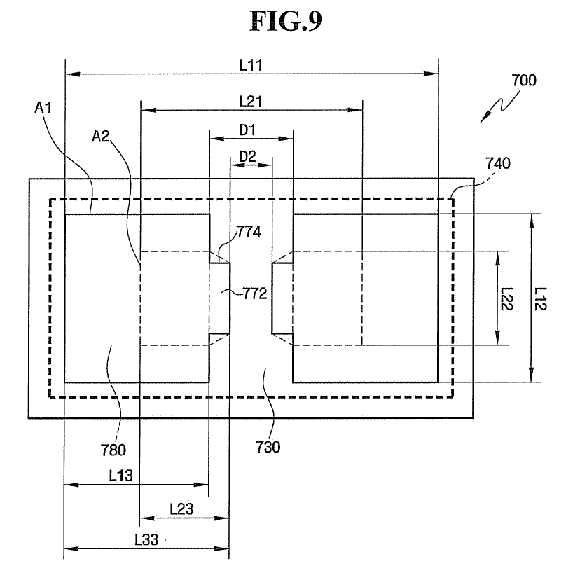

Another exemplary embodiment of a PCB 600 according to the present invention will hereinafter be described in detail with reference to FIG. 8. FIG. 8 illustrates a top plan view of the PCB 600. The exemplary embodiment of a PCB 600 illustrated in FIG. 8 is similar to the exemplary embodiment of a PCB 500 illustrated in FIG. 7, and therefore, like reference numerals will indicate like elements, and detailed descriptions thereof will be skipped.

Referring to FIG. 8, the PCB 600 includes first and second pads 660 and 670 on which SMDs (not shown) may be mounted and a dielectric region 630 on which no SMDs are mounted and which may be formed of solder resist. Each of the first and second pads 660 and 670 includes a main region 660a and 670a, respectively, and an expansion region 660b and 660c and 670b and 670c, respectively. Silk lines 640 may be printed on the PCB 600.

The expansion regions (660b and 660c and 670b and 670c) of each of the first and second pads 660 and 670 include a main expansion region 660b and 670b, respectively, which has a uniform width; and a pair of sub-expansion regions 660c and 670c, respectively, which are disposed on both sides of the main expansion region 660b and 670b, respectively, and have a decreasing width.

The expansion regions (660b and 660c) of the first pad 660 and the expansion regions (670b and 670c) of the second pad 670 extend from the main region 660a of the first pad 660 and the main region 670a of the second pad 670, respectively, so as to face each other.

According to the exemplary embodiment of FIG. 8, it is possible to reduce the probability of the occurrence of a short circuit due to first and second pads 660 and 670 being insufficiently spaced apart from each other. In addition, it is possible to reduce the probability of cold soldering occurring due to lack of solder.

Moreover, it is possible to improve sourcing flexibility for SMDs and reduce manufacturing costs. In addition, it is possible to readily respond to the necessity of design modifications for market demands or improving price competitiveness.

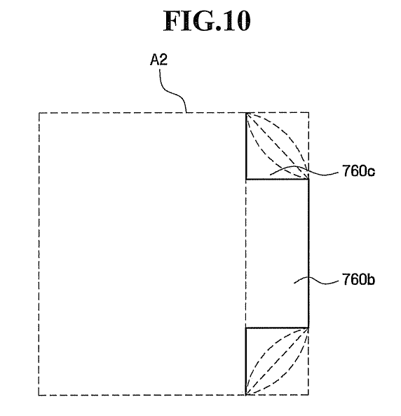

Another exemplary embodiment of a PCB 700 according to the present invention will hereinafter be described in detail with reference to FIGS. 9 and 10. FIG. 9 illustrates a top plan view of the PCB 700, and FIG. 10 illustrates a diagram of various exemplary embodiments of the shape of a pair of sub-expansion regions 760c and 770c illustrated in FIG. 9. The exemplary embodiment of a PCB 700 illustrated in FIG. 9 is similar to the exemplary embodiment of a PCB 600 illustrated in FIG. 8, and therefore like reference numerals will indicate like elements, and detailed descriptions thereof will be skipped.

Referring to FIG. 9, the PCB 700 includes first and second pads 760 and 770, respectively, on which SMDs (not shown) can be mounted and a dielectric region 730 on which no SMDs are mounted and which may be formed of solder resist. Each of the first and second pads 760 and 770 includes a main region 760a and 770a, respectively, and an expansion region 760b and 760c and 770b and 770c, respectively. Silk lines 740 may be printed on the PCB 700.

The expansion regions (760b and 760c and 770b and 770c) of each of the first and second pads 760 and 770 include a main expansion region 760b and 770b, respectively, which has a uniform width; and a pair of sub-expansion regions 760c and 770c, respectively, which are disposed on both sides of the main expansion region 760b and 770b, respectively, and have a decreasing width.

Referring to FIG. 10, dotted lines represent various shapes that can be employed by exemplary embodiments of the sub-expansion regions 760c and 770c. However, the present invention is not restricted to those illustrated in FIG. 10, but could encompass any shape as would be known to one of ordinary skill in the art.

As the size of the sub-expansion regions 760c and 770c decreases, the distance between the first and second pads 760 and 770 increases, and thus the probability of the occurrence of a short circuit decreases. In contrast, as the size of the sub-expansion regions 760c and 770c increases, the probability of cold soldering occurring due to lack of solder decreases. Therefore, the sub-expansion regions 760c and 770c may be formed in various shapes.

According to the exemplary embodiment illustrated in FIGS. 9 and 10, it is possible to improve sourcing flexibility for SMDs and reduce manufacturing costs. In addition, it is possible to improve price competitiveness and to readily respond to the necessity of design modifications for market demands or improving price competitiveness.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A printed circuit board comprising:
first and second pads spaced apart from each other; and
a dielectric region which surrounds the first and second pads,
wherein each of the first and second pads includes a main region and an expansion region which extends from the main region, and
wherein the main regions of the first and second pads are configured to have a first surface mount device mounted thereon,
wherein the expansion regions and portions of the main regions which directly adjoin the expansion regions of the first and second pads are configured to have a second surface mount device mounted thereon, and
wherein the first and second surface mount devices have different sizes.

2. The printed circuit board of claim 1, wherein the expansion region of the first pad and the expansion region of the second pad extend from the main region of the first pad and the main region of the second pad, respectively, so as to face each other.

3. The printed circuit board of claim 1, wherein a size of the main regions of the first and second pads is a standard size corresponding to a size of the first surface mount device.

4. The printed circuit board of claim 1, wherein a size of the expansion regions and portions of the main regions which directly adjoin the expansion regions of the first and second pads is a standard size corresponding to the size of the second surface mount device.

5. The printed circuit board of claim 1, wherein a distance between the expansion region of the first pad and the expansion region of the second pad is a standard distance corresponding to a size of the second surface mount device.

6. The printed circuit board of claim 1, wherein a distance between the main region of the first pad and the main region of the second pad is a standard distance corresponding to a size of the first surface mount device.

7. The printed circuit board of claim 1, wherein the expansion region of the first pad and the expansion region of the second pad extend from the main region of the first pad and the main region of the second pad, respectively, so as to face each other, and a distance between the expansion region of the first pad and the expansion region of the second pad is less than a standard distance corresponding to the size of the first surface mount device and greater than a standard distance corresponding to the size of the second surface mount device.

8. The printed circuit board of claim 1, wherein the expansion region of the first pad and the expansion region of the second pad extend from the main region of the first pad and the main region of the second pad, respectively, so as to face each other, and each of the expansion regions of the first and second pads comprises a main expansion region which has a uniform width and a sub-expansion region which is disposed on at least one side of the main expansion region and has a decreasing width.

9. The printed circuit board of claim 8, wherein a distance between the main expansion region of the first pad and the main expansion region of the second pad is a standard distance corresponding to a size of the second surface mount device and a distance between the sub-expansion region of the first pad and the sub-expansion region of the second pad is greater than the standard distance corresponding to the size of the second surface mount device.

10. The printed circuit board of claim 1, wherein the expansion region of the first pad and the expansion region of the second pad are both formed as trapezoids.

11. The printed circuit board of claim 1, wherein the first surface mount device has a standard metric package size of 1608 and the second surface mount device has a standard metric package size of 1005.

12. The printed circuit board of claim 1, wherein the expansion region of the first pad and the expansion region of the second pad extend from a middle part of the main region of the first pad and a middle part of the main region of the second pad, respectively, so as to face each other.

13. The printed circuit board of claim 1, wherein silk lines are printed over the dielectric region surrounding the first and second pads.

14. A method of mounting a surface mounted device on a printed circuit board, the method comprising:
providing a printed circuit board which comprises:
first and second pads spaced apart from each other; and
a dielectric region which surrounds the first and second pads,
wherein each of the first and second pads including a main region and an expansion region which extends from the main region; and
mounting one of a first surface mount device on the main regions of the first and second pads and mounting a second surface mount device on the extend regions and portions of the main regions which directly adjoin the expansion regions of the first and second pads.

15. A liquid crystal display comprising:
a display unit which comprises a liquid crystal panel and a first printed circuit board configured to drive the liquid crystal panel; and
a backlight unit which comprises a light source module and a second printed circuit board configured to drive the light source module and provide backlight to the display unit,
wherein at least one of the first and second printed circuit boards comprises:
first and second pads spaced apart from each other; and
a dielectric region which surrounds the first and second pads,
wherein each of the first and second pads includes a main region and an expansion region which extends from the main region, and
wherein the main regions of the first and second pads are configured to have a first surface mount device mounted thereon, wherein the expansion regions and portions of the main regions which directly adjoin the expansion regions of the first and second pads are configured to have a second surface mount device mounted thereon, and
wherein the first and second surface mount devices have different sizes.

16. The liquid crystal display of claim 15, wherein the expansion region of the first pad and the expansion region of the second pad extend from the main region of the first pad and the main region of the second pad, respectively, so as to face each other.

17. The liquid crystal display of claim 15, wherein a distance between the expansion region of the first pad and the expansion region of the second pad is a standard distance corresponding to a size of the second surface mount device.

18. The liquid crystal display of claim 15, wherein a distance between the main region of the first pad and the main region of the second pad is a standard distance corresponding to a size of the first surface mount device.

19. The liquid crystal display of claim 15, wherein the expansion region of the first pad and the expansion region of the second pad extend from the main region of the first pad and the main region of the second pad, respectively, so as to face each other, and each of the expansion regions of the first and second pads comprises a main expansion region which has a uniform width and a sub-expansion region which is disposed on at least one side of the main expansion region and has a decreasing width.

20. The liquid crystal display of claim 19, wherein a distance between the main expansion region of the first pad and the main expansion region of the second pad is a standard distance corresponding to a size of the second surface mount device and a distance between the sub-expansion region of the first pad and the sub-expansion region of the second pad is greater than the standard distance corresponding to the size of the second surface mount device.
